(19) United States
(12) Patent Application Publication
(10) Pub. No.: US 2025/0054934 A1
(43) Pub. Date: Feb. 13, 2025

(54) FORMING A CAVITY IN A REDISTRIBUTION LAYER OF AN IC PACKAGE TO REDUCE OVERSPREADING OF UNDERFILL MATERIAL

(71) Applicant: Taiwan Semiconductor Manufacturing Company, Ltd., Hsin-Chu (TW)

(72) Inventors: Wei-Yu Chou, Hsinchu (TW); Yang-Che Chen, Hsin-Chu city (TW); Yi-Lun Yang, Taoyuan City (TW); Ting-Yuan Huang, Yilan County (TW); Hsiang-Tai Lu, Hsinchu County (TW)

(21) Appl. No.: 18/366,327

(22) Filed: Aug. 7, 2023

(51) Int. Cl. H01L 25/18; H01L 23/00; H01L 23/31; H01L 23/522; H01L 23/528; H01L 25/00

(52) U.S. Cl. CPC H01L 25/18; H01L 23/3157; H01L 23/5226; H01L 23/528; H01L 24/05; H01L 24/13; H01L 25/50; H01L 2224/0401; H01L 2224/13111; H01L 2224/13116

(57) ABSTRACT

An integrated circuit (IC) package includes a first integrated circuit (IC) device. An interconnection structure is disposed over the first IC device in a cross-sectional side view. The interconnection structure includes a plurality of interconnection components. A cavity is disposed in the interconnection structure in the cross-sectional side view. A second IC device is disposed at least partially within the cavity in the cross-sectional side view. The second IC device is electrically coupled to the first IC device through at least a subset of the interconnection components of the interconnection structure. A non-metallic material partially fills the cavity. The second IC device is at least partially surrounded by the non-metallic material in the cross-sectional side view and in a top view.

### BACKGROUND

The semiconductor integrated circuitry (IC) industry has experienced rapid growth. Technological advances in IC design and material have produced generations of ICs where each generation has smaller and more complex circuits than previous generations. During the course of IC evolution, functional density (i.e., the number of interconnected devices per unit chip area) has generally increased while geometry size (i.e., the smallest component (or line) that can be created using a fabrication process) has decreased. Accommodate

As the semiconductor device scaling down continues, challenges in fabrication may arise. For example, a redistribution layer (RDL) structure may be formed as a part of an IC package for electrical signal routing. An IC device may be formed over the RDL structure, where the IC device is electrically coupled to the IC package. An underfill material is typically formed around the IC device. However, as semiconductor device sizes continue to shrink, the distances between the underfill material and other nearby components on the IC package (e.g., an under-bump metallization component) may also become smaller. This could cause the underfill material to spread onto these nearby components, which could adversely impact the performance or the intended operations of the IC package.

Therefore, although existing semiconductor fabrication methods have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1-25 are cross-sectional side views of an integrated circuitry (IC) package at various fabrication stages constructed according to various aspects of the present disclosure.

FIGS. 26A-26B, 27A-27B, and 28A-28B are top views of an integrated circuitry (IC) package constructed according to various aspects of the present disclosure.

FIG. 29 is a block diagram of a semiconductor fabrication system.

FIG. 30 is a flowchart of a method to fabricate an IC package in accordance with various aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

Integrated Circuitry (IC) chips contain a plurality of different types of microelectronic components, such as transistors, resistors, inductors, capacitors, etc. In some cases, an IC package may include a System on IC (or SoIC) device that contains a plurality of these microelectronic components. The IC package may also include a redistribution layer (RDL) structure that is formed over the IC device. The RDL structure may include a plurality of metallization layers (e.g., copper-based metallization layers) that can be used to facilitate electrical routing (and/or heat dissipation) for the IC package. For example, another type of IC device may be formed over the RDL structure. In some embodiments, the IC device formed over the RDL structure may be an Integrated Passive Device (IPD), which is an IC containing passive components such as capacitors, inductors, or resistors. The IPD may or may not contain active devices such as transistors. In other embodiments, the IC device formed over the RDL structure may include ICs containing active electrical circuitry (e.g., with transistors). Regardless of which type of IC devices are formed over the RDL structure, the RDL structure may provide electrical connectivity between the SoIC device (disposed below the RDL structure) and the IC device(s) formed over the RDL structure. Solder bumps may also be formed over the RDL structure to provide electrical connectivity to the SoIC device through the RDL structure.

An underfill material may be applied around the IC device that is formed over the RDL structure. The underfill material may include an adhesive material to enhance the attachment between the IC device and the RDL structure. The underfill material also helps to protect the IC device from contaminant sources and/or moisture. However, as IC device sizes continue to shrink, a distance between the IC device and other nearby components (e.g., the solder bumps) formed over the RDL structure may shrink as well. As such, the underfill material that is meant to surround the IC device (but not the nearby components, such as the solder bumps) may inadvertently spread to the nearby components. A capillary effect may exacerbate the spreading of the underfill material to nearby components such as the solder bumps. The unintentional overspreading of the underfill material could adversely affect the overall functioning of the IC package and is therefore undesirable.

To address the underfill overspreading issue, the present disclosure utilizes novel fabrication process flows to create a cavity in an RDL structure that is formed over an SoIC as a part of an IC package. The IC device is then formed at least partially in the cavity in the RDL structure, and then the underfill material is applied around the IC device in the cavity. The cavity serves as a reservoir to hold the underfill material therein, so that the underfill material does not leak out of the cavity. As such, the underfill material will not inadvertently spread to nearby components according to the present disclosure. Consequently, the overall performance of the IC package of the present disclosure is improved.

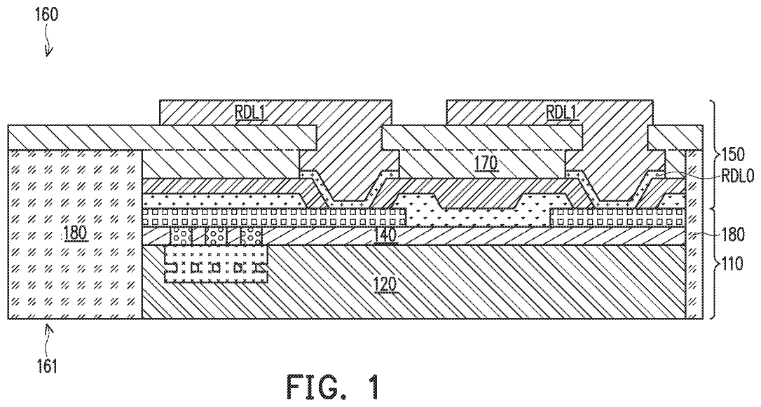

The process flows for implementing the various aspects of the present disclosure will now be discussed below with reference to FIGS. 1-25, which are diagrammatic fragmentary cross-sectional side view drawings of an IC package 100 constructed according to various aspects of the present disclosure in one embodiment.

Referring now to FIG. 1, the IC package 100 includes an IC device 110. In some embodiments, the IC device 110 includes a System on Integrated Circuit (SoIC) chip. In some embodiments, the SoIC chip may include different IC dies. For example, the SoIC chip may include an electronic memory (e.g., Static Random Access Memory (SRAM) or Dynamic Random Access Memory (DRAM)) die, as well as a logic device die that is electrically and/or physically coupled to the electronic memory die. The logic device die may include logic circuitry that is configured to operate and/or control the operations of the circuitry of the electronic memory die.

As shown in FIG. 1, the IC device 110 includes an IC substrate 120. In some embodiments, the IC substrate 120 includes a semiconductor substrate, such as a silicon substrate. Other types of substrates may also be implemented in other embodiments. The IC substrate 120 may include various IC components devices, such as field-effect transistors (FETs), memory cells, imaging sensors, passive devices, other devices, or combinations thereof. For example, the IC substrate 120 may include flat active regions with various IC devices, such as plain field-effect transistors (FETs). In some other embodiments, the IC substrate 120 may include fin (e.g., vertically protruding) active regions with various IC devices formed thereon. It is understood that the fin active regions may also be used to form gate-all-around (GAA) devices in some embodiments. Regardless of the type of transistors used, it is understood that these transistors may form the building blocks of the electrical circuitry of the electronic memory die and/or the logic device die of the SoIC chip. For reasons of simplicity, the details of the transistor layout/arrangement are not specifically illustrated or described herein.

The IC device 110 may also include a plurality of metal layers 140 formed over a side 160 of the IC device 110. In that regard, for ease of reference, the IC device 110 (or the IC package 100 itself) may have a side 160 and a side 161 that is opposite the side 160. The side 160 may also be referred to as a top side, and the side 161 may also be referred to as a bottom side. In some embodiments, the transistors (e.g., planar transistors, FinFETs, or GAA devices) of the IC device 110 may be formed at or near the side 160 of the IC substrate 120. The metal layers 140 may include metal lines and vias or contacts to provide electrical routing for the electrical circuitry of the IC device 110. The metal lines are distributed in multiple levels of metal layers, such as a first metal layer (e.g., a M1 layer), a second metal layer (e.g., a M2 layer), etc. For reasons of simplicity, the details of the metal layers 140 are not described herein.

Still referring to FIG. 1, the IC package 100 further includes an interconnection structure 150 (separate from the metal layers 140) formed over the metal layers 140. In some embodiments, the interconnection structure 150 may include a redistribution layer (RDL) structure that is configured to route electrical signals generated by the IC device 110, and/or to dissipate heat in certain situations. For example, as will be discussed in more detail below, the interconnection structure 150 may include a plurality of interconnection layers that contain electrically and/or thermally conductive components, which can be used to route the electrical signals and/or to dissipate heat. In some embodiments, the conductive components of the interconnection structure 150 are copper-based conductive components. As such, the RDL structure of the interconnection structure 150 may be referred to as a copper RDL structure. In other embodiments, the conductive components of the interconnection structure 150 may be nickel-based, or based on some other types of metallic material.

The interconnection structure 150 may include a plurality of RDL layers. At the stage of fabrication of FIG. 1, an RDL0 layer and an RDL1 layer are formed as a initial part of the interconnection structure 150. The RDL0 layer is the bottommost layer of the interconnection structure 150, and the RDL1 layer is the layer immediately above the RDL0 layer. Each of the RDL layers may include a conductive material, which as discussed above may be copper, nickel, or other types of metallic materials in various embodiments. The conductive material is surrounded by an isolation material 170, which helps to electrically isolate the conductive material of the RDL layers from other conductive components (e.g., nearby RDL components) that are not meant to be in electrical contact with the RDL layer. In other words, the isolation material 170 helps to prevent unintentional and undesirable electrical shorting.

The isolation material 170 is a non-metallic material that is capable of providing electrical isolation to the various conductive components (e.g., the RDL layers) of the interconnection structure 150. In some embodiments, the isolation material 170 includes a polymer material. In other embodiments, the isolation material 170 includes a dielectric material, such as silicon oxide. In any case, it is understood that the cavity in the interconnection structure 150 may be formed in a manner to expose any one of the RDL layers according to various embodiments of the present disclosure. In the embodiment associated with FIGS. 1-13, the cavity is formed to expose the RDL1 layer, such that the IC device (e.g., the IPD) formed in the cavity will be bonded to the RDL1 layer, as discussed in more detail below. However, the cavity may expose the RDL0 in some other embodiments, or even an RDL2 layer (to be formed later) in yet other embodiments.

Still referring to FIG. 1, the IC package 100 further includes a molding material 180 that surrounds the IC device 110 and at least portion of the interconnection structure 150. In the cross-sectional side view of FIG. 1, the molding material 180 is shown as being located on the opposite side surfaces of the IC substrate 120, the metal layers 140, and the isolation material 170 of the interconnection structure 150. The molding material 180 may provide protection to portions of the IC package 100 surrounded by the molding material 180.

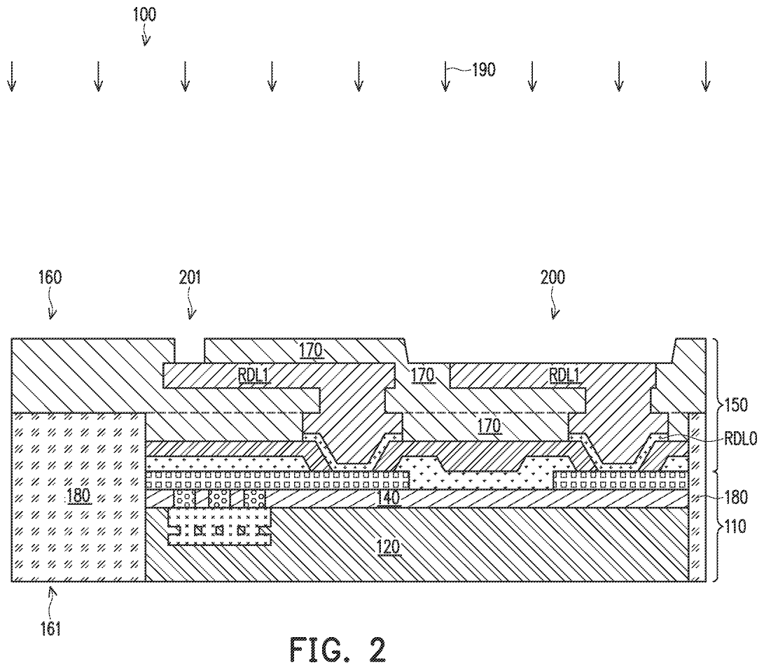

Referring now to FIG. 2, a coating and patterning process 190 is performed to the IC package 100. As a first step of the coating and patterning process 190, a coating process is performed to coat additional portions of the isolation material 170 over and around the RDL1 layer of the interconnection structure 150. In some embodiments, the coating process may include one or more deposition processes, such as chemical vapor deposition (CVD), physical vapor deposition (PVD), atomic layer deposition (ALD), or combinations thereof. In some embodiments, the deposited isolation material 170 includes polymer, or silicon oxide. As a second step of the coating and patterning process 190, a photolithography patterning process is performed to the deposited isolation material 170. For example, the photolithography patterning process may include one or more photoresist spin coating, pre-exposure baking, exposing, post-exposure baking, and/or developing processes. The photolithography patterning process forms a plurality of cavities in the interconnection structure 150. For example, a cavity 200 is formed to expose at least a portion of a first one of the RDL1 layers (e.g., the one on the right in FIG. 2), and a cavity 201 is formed to expose at least a portion of a second one of the RDL1 layers (e.g., the one on the left in FIG. 2).

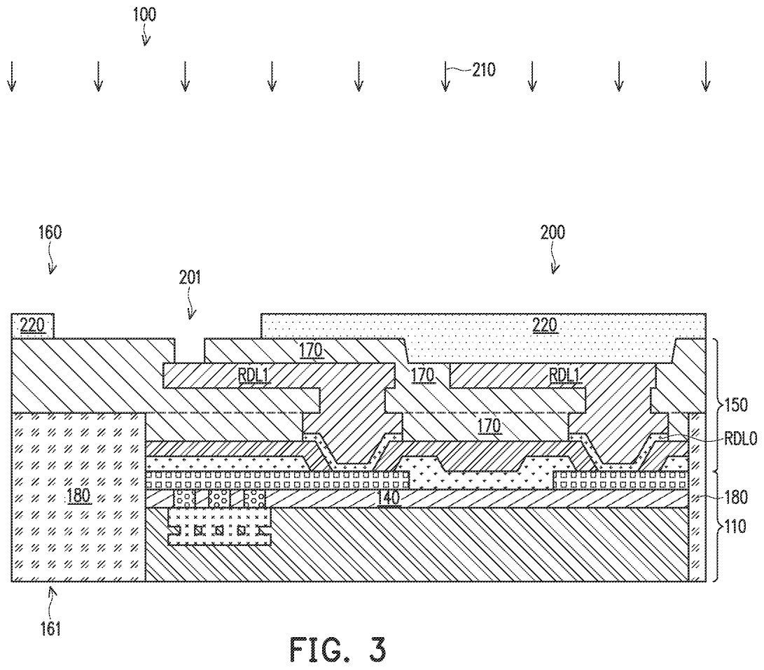

Referring now to FIG. 3, a photoresist coating process 210 is performed to the IC package 100 to form a patterned photoresist layer 220. In some embodiments, the photoresist coating process 210 includes a photoresist spin coating process. One or more photoresist exposure, baking, and developing processes may also be performed to define the patterned photoresist layer 220. The patterned photoresist layer 220 fills the cavity 200 but still leaves the cavity 201 exposed. At this stage of fabrication, the cavity 201 also includes not just the portion of the cavity that extends vertically through the isolation material 170, but it may also include the portion of the cavity that extends vertically through a portion of the photoresist layer 220, which exposes portions of the isolation material 170.

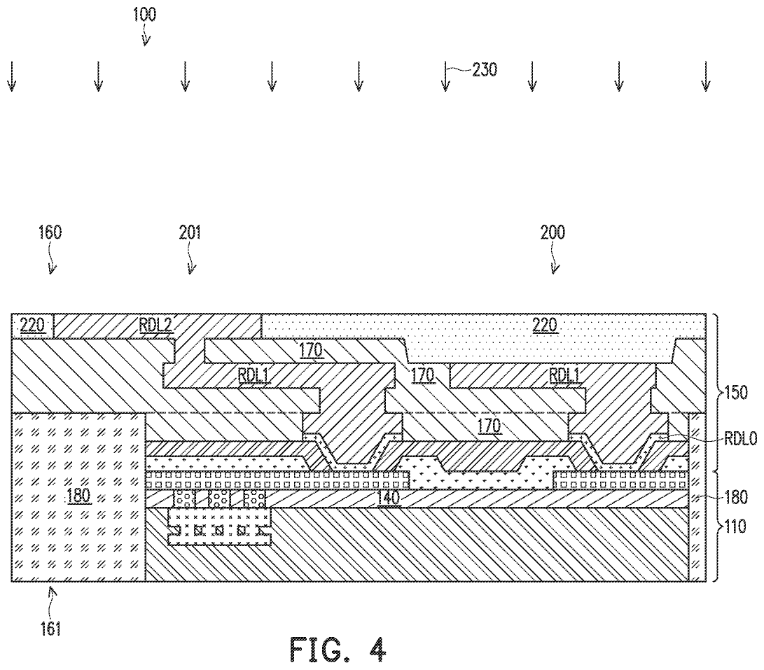

Referring now to FIG. 4, a deposition process 230 is performed to the IC package 100 to form an RDL2 layer of the interconnection structure 150. In some embodiments, the deposition process 230 may include one or more CVD, PVD, or ALD processes. The deposition process 230 deposits a conductive material, such as copper or nickel in the cavity 201 to form the RDL2 layer in the cavity 201. The RDL2 layer is electrically connected to the RDL1 layer below. Due to the cavity 200 being covered up by the photoresist layer 220, no RDL2 layer is formed in the cavity 200. It is understood that in some embodiments, a planarization process, such as a chemical mechanical polishing (CMP) process, may be performed following the deposition of the conductive material to remove excess portions of the conductive material outside the cavity 201.

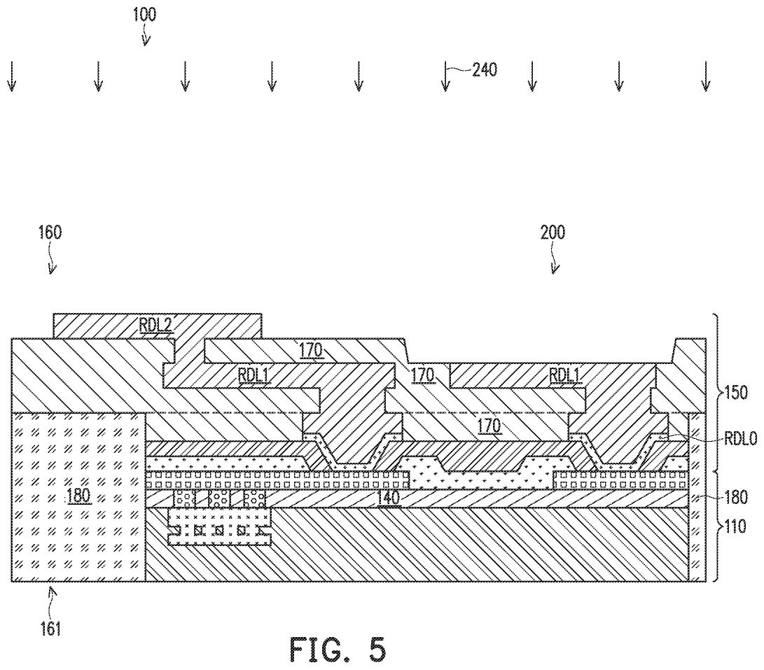

Referring now to FIG. 5, a photoresist removal process 240 is performed to the IC package 100 to remove the photoresist layer 220. In some embodiments, the photoresist removal process 240 may include a photoresist stripping process, or a photoresist ashing process. As a result of the performance of the photoresist removal process 240, the RDL2 layer is exposed, and the portion of the RDL1 layer located underneath the cavity 200 is also exposed.

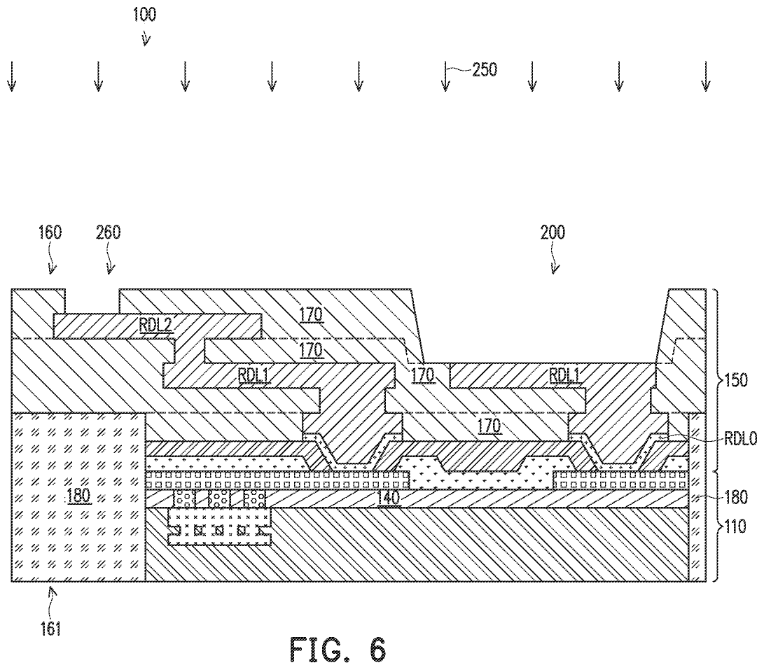

Referring now to FIG. 6, a coating and patterning process 250 is performed to the IC package 100. As a first step of the coating and patterning process 250, a coating process is performed to form additional portions of the isolation material 170 over and around the RDL2 layer of the interconnection structure 150. Portions of the isolation material 170 may also be coated over the RDL1 layer underneath the cavity 200. In some embodiments, the coating process may include one or more deposition processes, such as CVD. PVD, ALD, or combinations thereof. In some embodiments, the deposited isolation material 170 includes polymer, or silicon oxide. As a second step of the coating and patterning process 250, a photolithography patterning process is performed to the deposited isolation material 170. For example, the photolithography patterning process may include one or more photoresist spin coating, pre-exposure baking, exposing, post-exposure baking, and/or developing processes. The photolithography patterning process forms a cavity 260 in the isolation material 170, where the cavity 260 at least partially exposes the RDL2 layer. The cavity 200 (exposing the RDL1 layer) is also substantially maintained as a result of the photolithography patterning process, though its depth is increased by the deposition of the additional isolation material 170.

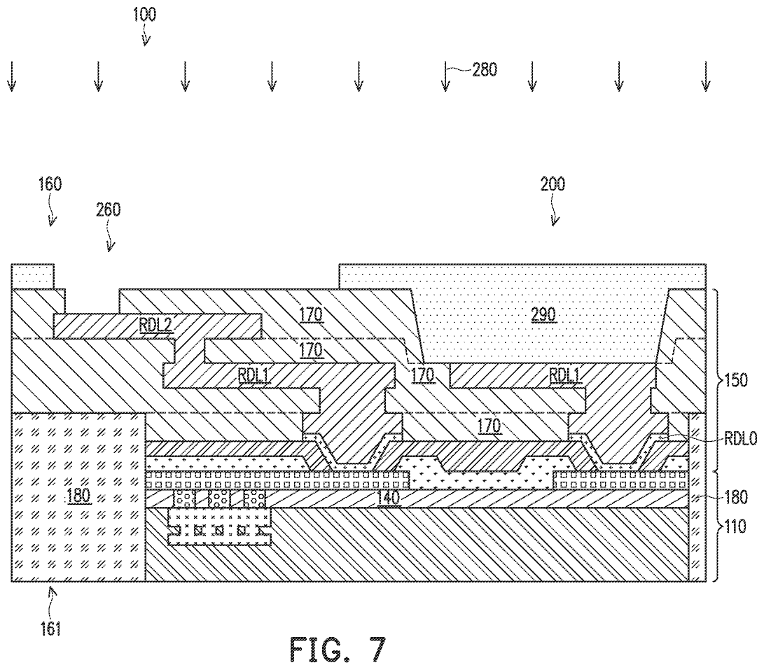

Referring now to FIG. 7, a photoresist coating process 280 is performed to the IC package 100 to form a patterned photoresist layer 290. In some embodiments, the photoresist coating process 280 includes a photoresist spin coating process. One or more photoresist exposure, baking, and developing processes may also be performed to define the patterned photoresist layer 290. The patterned photoresist layer 220 fills the cavity 200 but leaves the cavity 260 exposed. At this stage of fabrication, the cavity 260 also includes not just the portion of the cavity that extends vertically through the isolation material 170, but it may also include the portion of the cavity that extends vertically through a portion of the photoresist layer 290, which exposes portions of the isolation material 170.

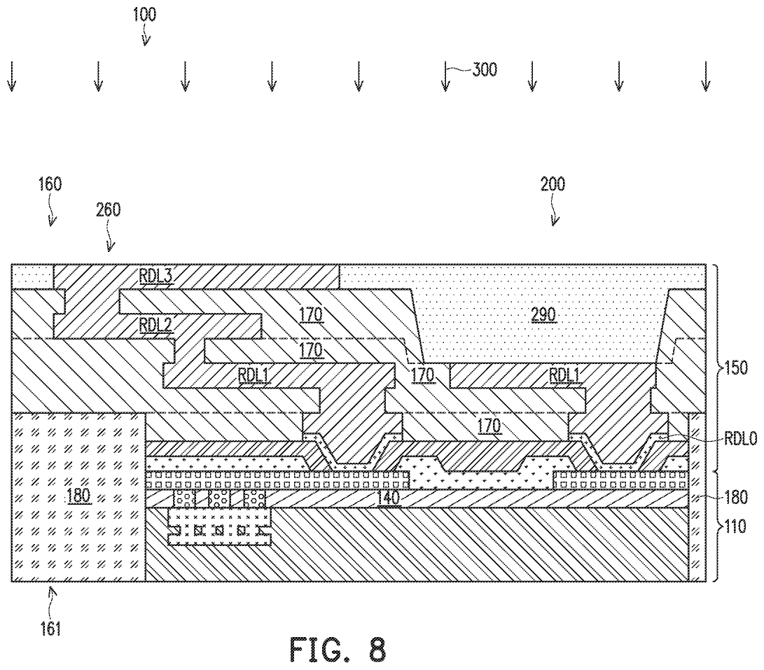

Referring now to FIG. 8, a deposition process 300 is performed to the IC package 100 to form an RDL3 layer of the interconnection structure 150. In some embodiments, the deposition process 300 may include one or more CVD, PVD, or ALD processes. The deposition process 230 deposits a conductive material, such as copper or nickel in the cavity 260 to form the RDL3 layer in the cavity 260. The RDL3 layer is electrically connected to the RDL2 layer below. Due to the cavity 200 being covered up by the photoresist layer 220, no RDL3 layer is formed in the cavity 200. It is understood that in some embodiments, a planarization process, such as a CMP process, may be performed following the deposition of the conductive material to remove excess portions of the conductive material outside the cavity 260.

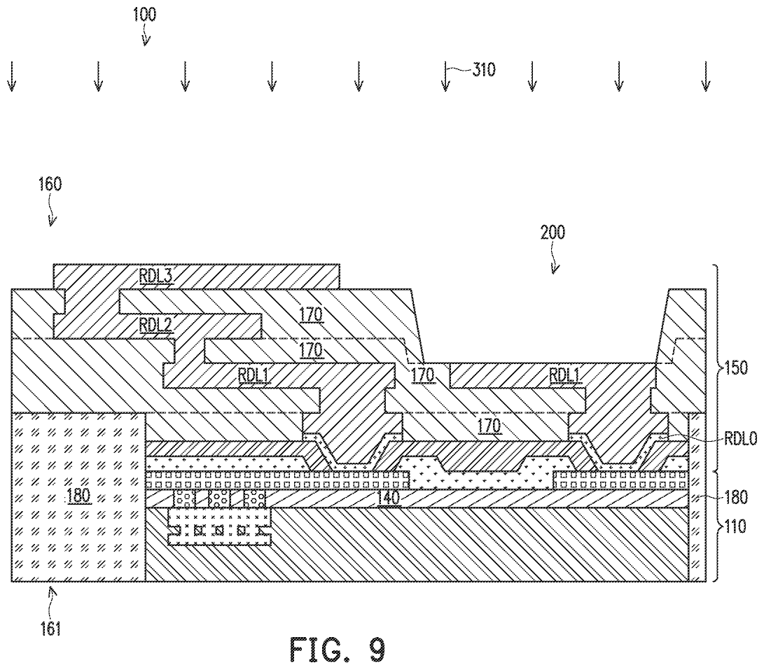

Referring now to FIG. 9, a photoresist removal process 310 is performed to the IC package 100 to remove the photoresist layer 290. In some embodiments, the photoresist removal process 240 may include a photoresist stripping process, or a photoresist ashing process. As a result of the performance of the photoresist removal process 310, the RDL3 layer is exposed, and the portion of the RDL1 layer located underneath the cavity 200 is also exposed.

The fabrication processes discussed above may be repeated in a plurality of cycles to complete the formation of the interconnection structure 150. For example, each of the cycles may include the formation and patterning of the isolation material, the coating of the patterned photoresist layer to cover the cavity 200, the formation of RDL layers, and the subsequent removal of the patterned photoresist layer. For reasons of simplicity, the present disclosure illustrates the formation of three RDL layers: RDL1. RDL2, and RDL3, where the RDL1 is the intended landing layer for the IC device (e.g., an IPD) that is yet to be formed over the side 160 and in the cavity 200. However, it is understood that the interconnection structure 150 may include any number of RDL layers (e.g., four, five, six or more), and that any one of the RDL layers may be used as the landing layer for the IC device to be formed over the side 160.

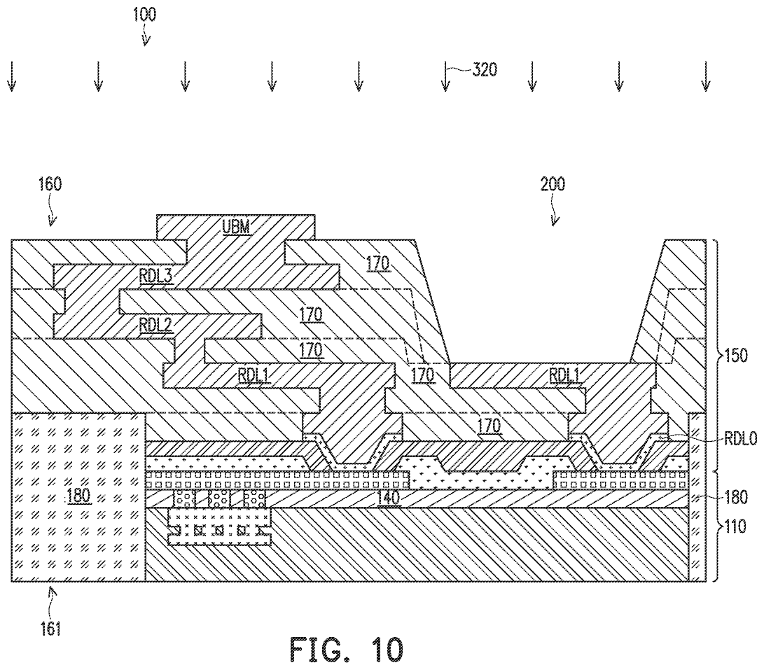

Referring now to FIG. 10, a UBM formation process 320 is performed to the IC package 100 to form a UBM structure. In that regard, the UBM formation process 320 may include one or more of the fabrication processes used to form the RDL layers. For example, the UBM formation process 320 may include a coating process to coat an additional portion of the isolation material 170 around the RDL3, a coating process of a patterned photoresist layer to cover the cavity 200, a formation of the UBM structure (e.g., by using the patterned photoresist layer to define the UBM structure), and the subsequent removal of the patterned photoresist layer. In this manner, the UBM structure may be viewed as another RDL layer of the interconnection structure. However, in some embodiments, the UBM structure may be configured to have a different material composition and/or a different thickness than the rest of the RDL layers of the interconnection structure 150, since the purpose of the UBM structure is to serve as a landing pad for a solder bump.

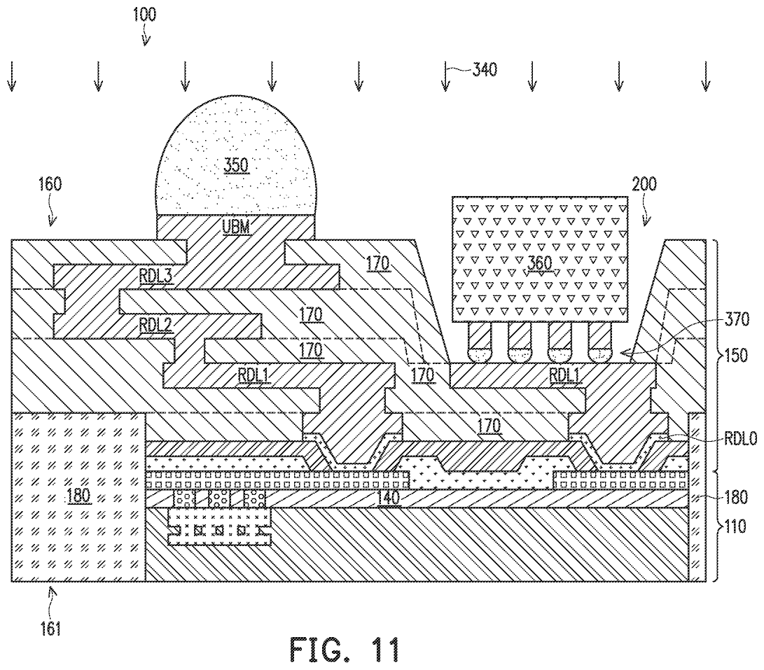

Referring now to FIG. 11, solder bump and IC device formation processes 340 are performed to the IC package 100 to form a solder bump 350 and an IC device 360. As shown in FIG. 11, the solder bump 350 is formed on the UBM. In some embodiments, the solder bump 350 includes a metal alloy material that is meltable under a hot temperature. For example, the metal alloy material may be made of tin and/or lead, and it may melt under a hot iron when the hot iron reaches a temperature of about 600 degrees Fahrenheit or greater. Due to its melting properties, the solder bump 350 may serve as an electrical conduit between the IC device 110 and other external devices. For example, an external device may be configured to come into direct physical contact with the solder bump 350, and the heat is applied to melt the solder bump 350. This allows the external device to establish a good electrical connection to the UBM, which allows the external device to electrically communicate with the electrical circuitry of the IC device 110 at least in part through the RDL layers of the interconnection structure 150.

According to various aspects of the present disclosure, the IC device 360 is placed at least partially within the cavity 200. For example, a bottom surface of the IC device 360 is less vertically elevated than an upper surface of the uppermost isolation material 170, though an upper surface of the IC device 360 is more vertically elevated than the upper surface of the uppermost isolation material 170. In other words, the bottom surface of the IC device 360 is located closer to the IC device 110 than the upper surface of the uppermost isolation material 170, but the upper surface of the IC device 360 is located farther from the IC device 110 than the upper surface of the uppermost isolation material 170. Or alternatively stated, the upper surface of the uppermost isolation material 170 has a vertical elevation that is in between the vertical elevation of the bottom surface of the IC device 360 and the vertical elevation of the top surface of the IC device 360.

In some embodiments, the IC device 360 includes an Integrated Passive Device (IPD), which is an IC containing passive components such as capacitors, inductors, or resistors. For example, an IPD may include a three-dimensional capacitor structure, such as a deep trench capacitor. In some embodiments, the IPD may or may not contain active devices such as transistors. It is understood that the IC device 360 is not limited to IPDs. In some embodiments, the IC device 360 may include ICs containing active devices such as transistors. Regardless of the type of device that the IC device 360 is implemented as, the IC device 360 is electrically coupled to the RDL1 layer through a plurality of interconnecting components 370, which may be in the form of bonding pads or solder bumps. As such, the IC device 360 is electrically coupled to the electrical circuitry of the IC device 110 at least in part through the RDL1 layer and the RDL0 layer.

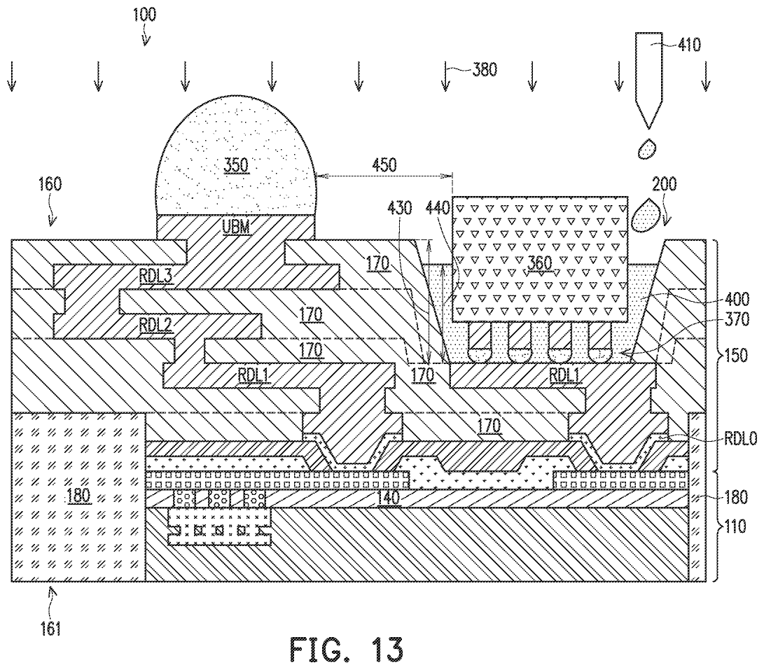

The implementation of the IC device 360 at least partially within the cavity 200 is one of the unique physical characteristics of the IC package 100 of the present disclosure. Conventional IC packages lack such a cavity 200, and thus any IC device implemented over the RDL structure would have to be implemented over the topmost RDL layer. As discussed above, this could lead to an overspreading of the underfill material (to be formed in a step discussed below with reference to FIG. 13), which is undesirable. In addition, the conventional way of implementing the IC device 360 (e.g., not inside a cavity) may entail a relatively long distance between the IC device bonded to the RDL structure and the SoIC that is below the RDL structure. Such a long distance may increase the parasitics, such as parasitic inductance and/or parasitic resistance.

In contrast, the fact that the IC device 360 is located at least partially within the cavity 200 effectively reduces the distance (e.g., by more than 20 microns in some embodiments) between the IC device 360 and the IC device 110 (e.g., the SoIC device), since the electrical signals traveling between the IC device 360 and the IC device 110 would be able to bypass the RDL layers above the RDL layer RDL1. In other words, the electrical signals would propagate through the RDL layers RDL1 and RDL0, but not the RDL layers RDL2 and RDL3. Consequently, the parasitics may be reduced. For example, the shorter distance may lead to a reduction in an Equivalent Series Inductance (ESL) or an Equivalent Series Resistance (ESR). As a result, the overall device performance of the IC package 100 may be improved.

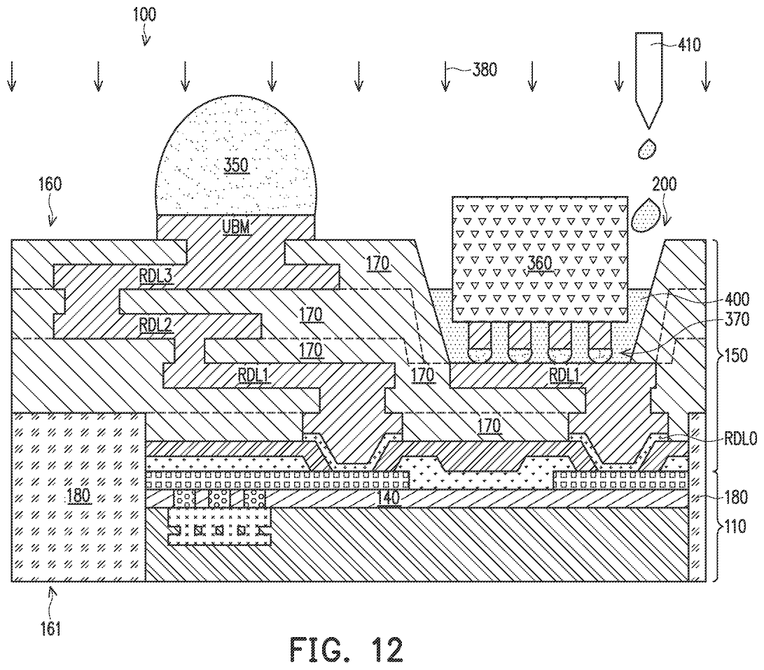

Referring now to FIG. 12, an underfill material dispensing process 380 is performed to partially fill the cavity 200 with an underfill material 400. In some embodiments, the underfill material 400 is dispensed via a nozzle 410. In some embodiments, the nozzle 410 is capable of dispensing the underfill material 400 using a jet dispensing process. In some embodiments, the underfill material 400 may include a non-metallic glue-like material that is capable of providing electrical insulation and physical protection. For example, the underfill material 400 may have a relatively low viscosity, a relatively high glass transition temperature, a relatively low thermal expansion coefficient, and a relatively good adhesiveness. The underfill material 400 may also contain inorganic particles that can be dispersed relatively easily in the space filled by the underfill material 400, which in this case is the lower portion of the cavity 200. In some embodiments, the underfill material 400 includes epoxy resin.

As shown in FIG. 12, the underfill material 400 fills the spaces between the IC device 360 and the RDL1 layer, including around the interconnecting components 370. Due to the aforementioned properties of the underfill material 400, it can adequately maintain the bonding between the IC device 360 and the RDL1 layer, as well as to shield the portions of the IC device 360 encapsulated therein from other contaminant sources (e.g., dust or moisture) and from mechanical forces that could cause damage to the IC device 360.

Referring now to FIG. 13, the underfill material dispensing process 380 may continue to be performed, so that more of the cavity 200 is filled by the underfill material 400. How much of the cavity 200 is intended to be filled by the underfill material 400 can be precisely configured. For example, a distance 430 between an uppermost surface of the interconnection structure 150 (e.g., the exposed upper surface of the isolation material 170) and an upper surface of the RDL1 layer may be known by design. A size (e.g., a volume) of the cavity 200 may also be configured by the fabrication processes discussed above. A rate at which the underfill material 400 is dispensed by the nozzle 410 is also known, which is also configurable. Based on the above factors, the amount of dispensing time can be calculated to control the amount of the underfill material 400 filling the cavity 200, such that the underfill material 400 does not over-fill the cavity 200. In other words, the underfill material dispensing process 380 is configured to ensure that a depth 440 of the underfill material 400 (e.g., corresponding to a distance between the upper surface of the underfill material 400 in the cavity 200 and the upper surface of the RDL1 layer) is smaller than the distance 430. In other words, the upper surface of the underfill material 400 is less elevated vertically than the uppermost surface of the interconnection structure 150. Such a configuration reduces the likelihood of the underfill material 400 spilling out of the cavity 200 and spreading onto nearby components like the solder bump 350.

As discussed above, the formation of the cavity 200 and the implementation of the IC device 360 in the cavity 200 offers various benefits. One of the benefits is that the closer distance between the IC device 360 and the IC device 110 translates into reduced parasitic inductance and/or reduced parasitic resistance. Another one of the benefits is that the underfill material 400 can be kept within the cavity 200, which reduces the likelihood of the underfill material overspreading onto nearby components such as the solder bump 350. The reduction in the likelihood of overspreading of the underfill material 400 means that a distance 450 (between about 10 microns and about 100 microns in some embodiments) between the IC device 360 and the solder bump 350 can also be reduced.

In more detail, conventional IC packages may have to designate a “keep-out zone” around an IC device similar to the IC device 360. Components around such an IC device should be kept away from the keep-out zone, so as to minimize the risk of the overspreading of the underfill material onto the nearby components. However, such a keep-out zone creates an undue burden on IC design and manufacturing, especially since IC device real estate is precious, and the keep-out zone may translate into wasted space. In comparison, due to the retention of the underfill material 400 within the cavity 200, the IC device 360 may not need a keep-out zone around it at all. Even if a keep-out zone is designated around the IC device 360 as a precautionary measure, the keep-out zone's size may be substantially reduced compared to conventional IC packages. In other words, the solder bump 350 and the IC device 360 can now be implemented to be closer with respect to one another, without elevating the risks of the underfill material 400 spreading onto the solder bump 350.

Note that the embodiment of FIG. 13 also does not need dam structures to block the potential overspreading of the underfill material 400. Nevertheless, a dam structure (e.g., a pillar-like structure that protrudes vertically upwards) may still be implemented between the solder bump 350 and the IC device 360 to block any underfill material 400 that spills out of the cavity 200. Since any inadvertently spilled underfill material 400 would have to climb over such a dam structure first before reaching the solder bump 350, the presence of the dam structure can further prevent the solder bump 350 (or other nearby components of the IC device 360) from coming into contact with the underfill material 400.

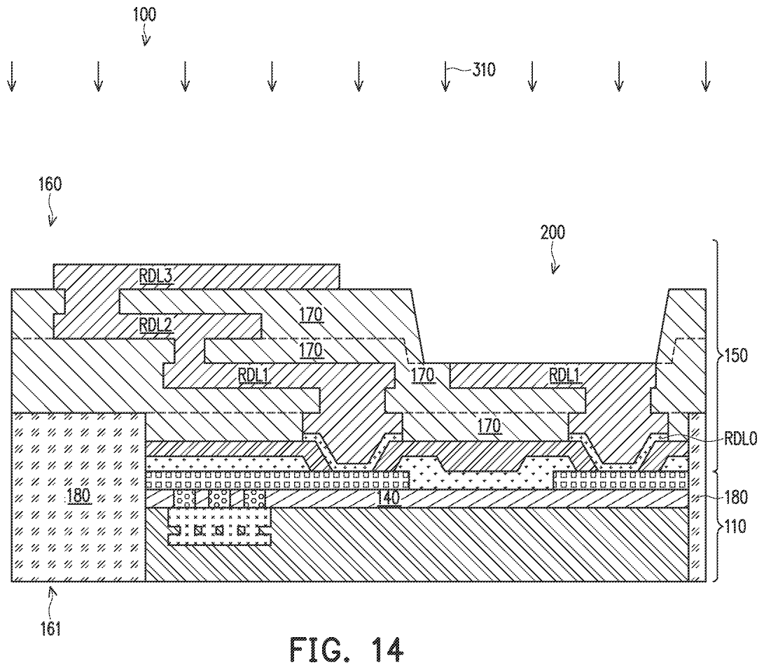

FIGS. 1-13 correspond to a first embodiment of the present disclosure, where the cavity 200 in the interconnection structure 150 is filled by the underfill material 400 having a different material composition than the isolation material 170. FIGS. 14-17 (to be discussed below) correspond to a second embodiment of the present disclosure, where the cavity 200 in the interconnection structure 150 is filled by the isolation material 170. For reasons of consistency and clarity, similar components appearing in both the first embodiment and the second embodiment will be labeled the same.

Referring now to FIG. 14, the IC package 100 has already undergone the fabrication processes discussed above with reference to FIGS. 1-9. That is, the RDL1. RDL2, and RDL3 layers of the interconnection structure 150 have already been formed over the side 160 of the IC package 100. The cavity 200 has also been formed in the interconnection structure 150, where the cavity 200 exposes one of the RDL1 layers. The patterned photoresist layer 290 (see FIG. 8) has also been removed by the photoresist removal process 310. Thus, both the RDL3 layer and the RDL1 layer are exposed at this stage of fabrication.

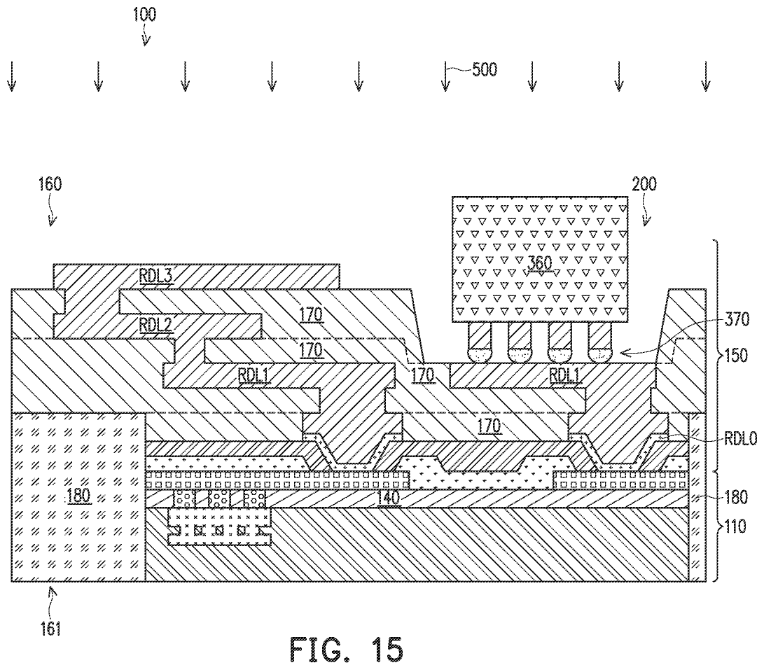

Referring now to FIG. 15, an IC device coupling process 500 is performed to couple the IC device 360 to the IC package 100. The IC device 360 is electrically coupled to the RDL1 layer through the plurality of interconnecting components 370. Again, the IC device 360 is implemented at least partially within the cavity 200, such that bottom surface of the IC device 360 is below the upper surface of the uppermost isolation material 170 vertically. However, the upper surface of the IC device 360 is still above the upper surface of the uppermost isolation material 170 vertically. As discussed above, the IC device 360 may include an IPD in some embodiments, or it may include active devices such as transistors in other embodiments.

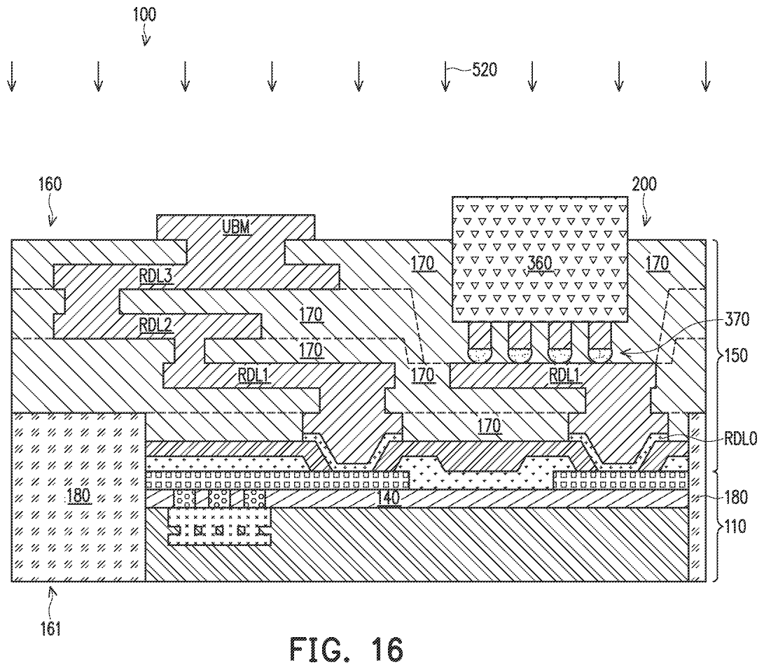

Referring now to FIG. 16, an isolation material and UBM formation process 520 is performed to fill the cavity 200 with the isolation material 170, as well as to form the UBM structure over the RDL3 layer. In more detail, one or more deposition processes, such as a CVD process, a PVD process, or an ALD process, may be performed to deposit the isolation material 170 in the cavity 200. The isolation material 170 may fill the cavity completely and surround portions of the IC device 360 (including the interconnecting components 370). In other words, portions of the IC device 360 are embedded within the isolation material 170. In some embodiments, the isolation material 170 includes a polymer material. In other embodiments, the isolation material 170 includes a silicon oxide material. The isolation material 170 may also embed the RDL3 layer therein. The UBM structure is also formed over the isolation material 170. The UBM structure is electrically coupled to the RDL3 layer of the interconnection structure 150.

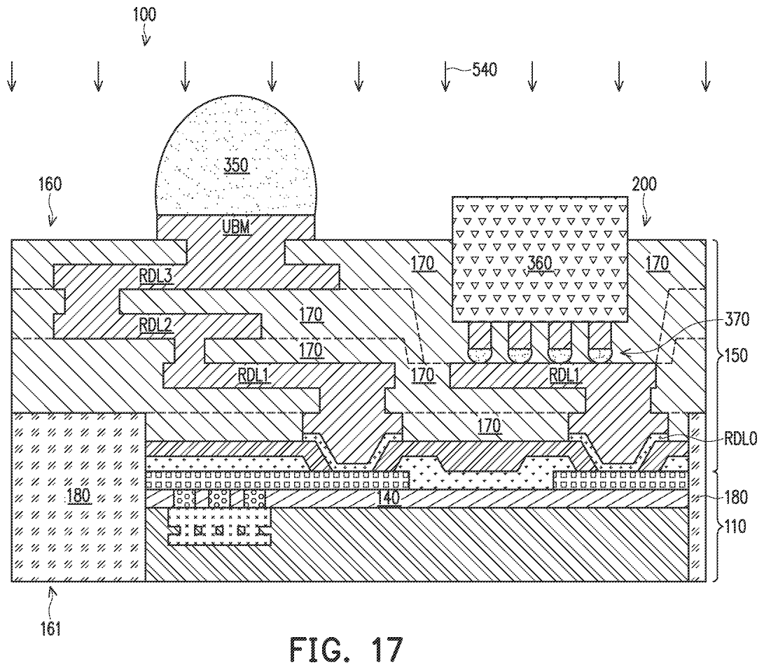

Referring now to FIG. 17, a solder bump formation process 540 is performed to form a solder bump 350 over the UBM structure. As discussed above with reference to the first embodiment, the solder bump 350 may include a metal alloy material, such as a metal alloy based on tin and/or lead. The solder bump 350 serves as an electrical access point for the electrical circuitry within the IC device 110.

Although the cavity 200 is filled by the isolation material 170 in the second embodiments, rather than by the underfill material 400 in the first embodiment, the second embodiment can still substantially achieve the same benefits discussed above with reference to the first embodiment. For example, since the IC device 360 is located at least partially within the cavity 200, it is closer to the IC device 110. This distance reduction can effectively reduce the parasitics, such as parasitic inductance and/or parasitic resistance, which in turn can improve device performance. In addition, since the underfill material 400 is not used in the second embodiment, there is no risk of the underfill material overflowing and spreading to nearby components such as the solder bump 350. The elimination of the underfill material 400 does not interfere or otherwise alter the proper operation of the IC package 100, since the isolation material 170 can still effectively maintain the attachment of the IC device 360 to the RDL1 layer, as well as to protect the components of the IC device 360 and/or the interconnection components 370 from contaminant particles or mechanical forces.

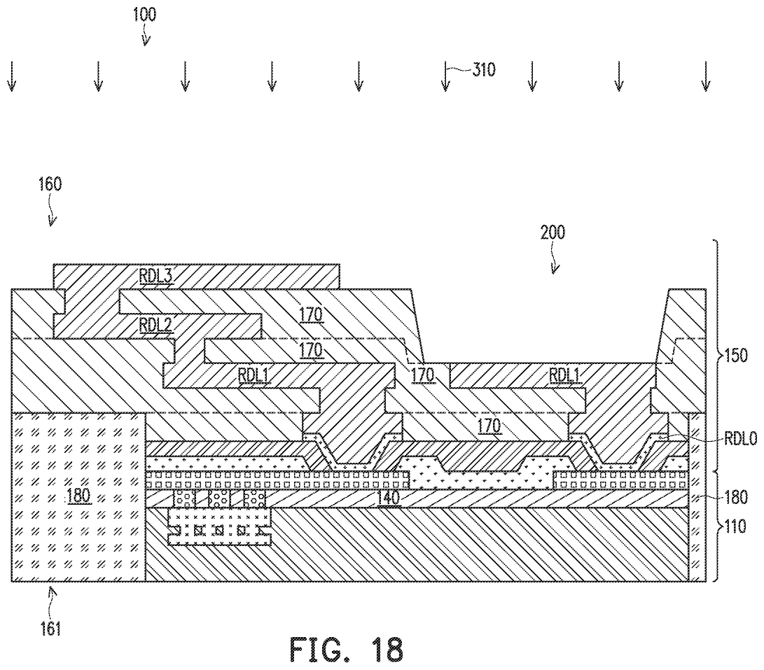

FIGS. 18-22 (to be discussed below) correspond to a third embodiment of the present disclosure, where the cavity 200 in the interconnection structure 150 is filled by a combination of the underfill material 400 and the isolation material 170. For reasons of consistency and clarity, similar components appearing in the first embodiment, the second embodiment, and the third embodiment will be labeled the same.

Referring now to FIG. 18, the IC package 100 has already undergone the fabrication processes discussed above with reference to FIGS. 1-9. That is, the RDL1, RDL2, and RDL3 layers of the interconnection structure 150 have already been formed over the side 160 of the IC package 100. The cavity 200 has also been formed in the interconnection structure 150, where the cavity 200 exposes one of the RDL1 layers. The patterned photoresist layer 290 (see FIG. 8) has also been removed by the photoresist removal process 310. Thus, both the RDL3 layer and the RDL1 layer are exposed at this stage of fabrication.

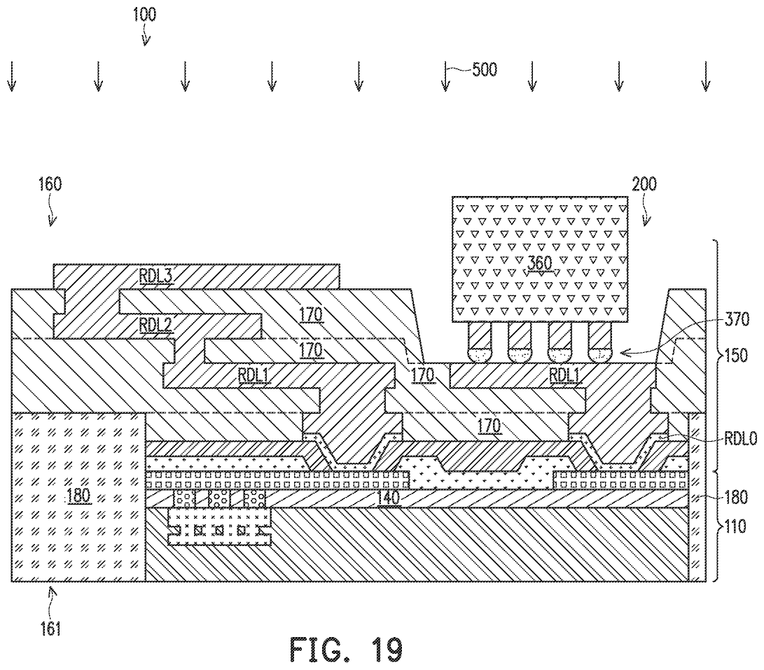

Referring now to FIG. 19, the IC device coupling process 500 (see FIG. 15) is performed to couple the IC device 360 to the IC package 100. For example, the IC device 360 may be bonded to the RDL1 layer through the plurality of interconnecting components 370. Again, the IC device 360 is implemented at least partially within the cavity 200, such that bottom surface of the IC device 360 is below the upper surface of the uppermost isolation material 170 vertically. However, the upper surface of the IC device 360 is still above the upper surface of the uppermost isolation material 170 vertically. As discussed above, the IC device 360 may include an IPD in some embodiments, or it may include active devices such as transistors in other embodiments.

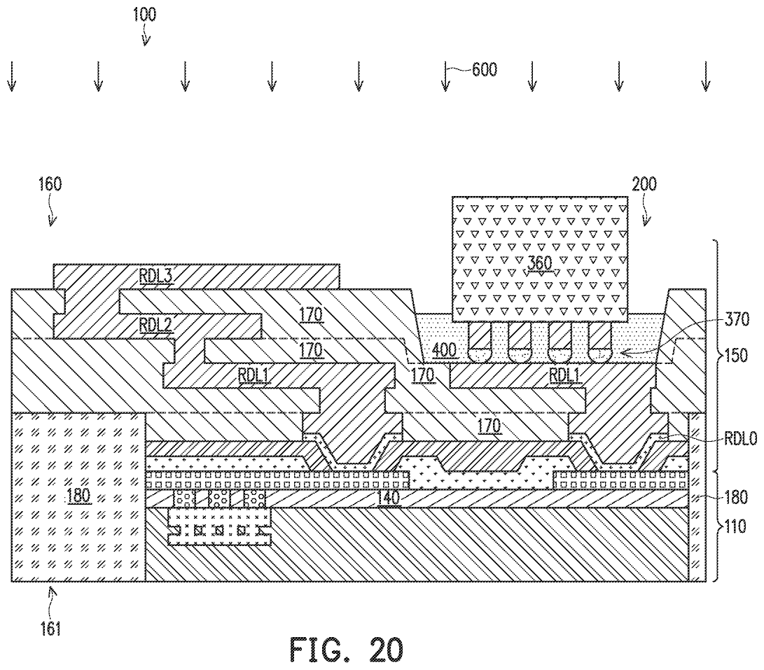

Referring now to FIG. 20, an underfill formation process 600 is performed to partially fill the cavity 200 with the underfill material 400. In some embodiments, the underfill material 400 may be dispensed via the nozzle 410 (see FIG. 12), for example, through a jet dispensing process. As discussed above, the glue-like properties of the underfill material 400 allows it to facilitate the attachment of the IC device 360 (specifically, the interconnection components 370) to the RDL1 layer below. The underfill material 400 also shields portions of the IC device 360 and the interconnection components 370 from contaminant sources (e.g., dust or moisture) and mechanical forces that could cause damage to the IC device 360.

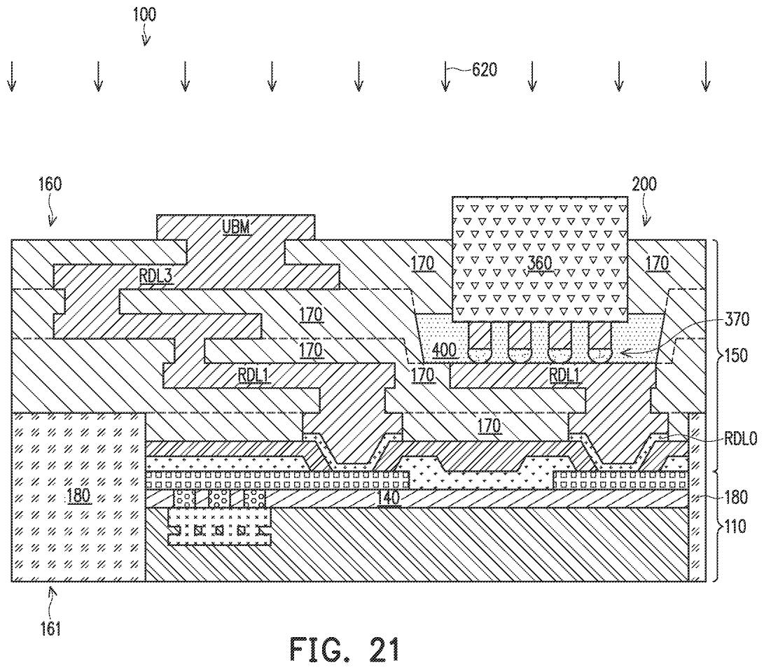

Referring now to FIG. 21, an isolation material and UBM formation process 620 is performed to fill the cavity 200 with the isolation material 170, as well as to form the UBM structure over the RDL3 layer. In more detail, one or more deposition processes, such as a CVD process, a PVD process, or an ALD process, may be performed to deposit the isolation material 170 on the underfill material 400 in the cavity 200. As discussed above, the isolation material 170 may include a polymer material or a silicon oxide material in various embodiments. The isolation material 170 and the underfill material 400 collectively may fill the cavity 200 completely and embed portions of the IC device 360 therein. The isolation material 170 may also embed the RDL3 layer therein. The UBM structure is also formed over the isolation material 170. The UBM structure is electrically coupled to the RDL3 layer of the interconnection structure 150.

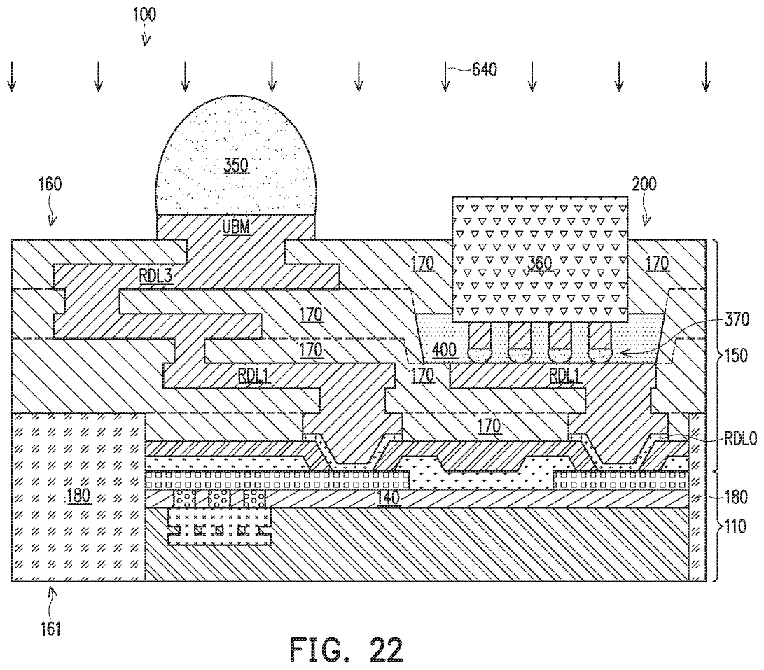

Referring now to FIG. 22, a solder bump formation process 640 is performed to form the solder bump 350 over the UBM structure. As discussed above with reference to the first embodiment or the second embodiment, the solder bump 350 may include a metal alloy material, such as a metal alloy based on tin and/or lead. The solder bump 350 serves as an electrical access point for the electrical circuitry within the IC device 110.

Based on the above discussions, it can be seen that the cavity 200 is filled by a combination of the underfill material 400 and the isolation material 170 in the third embodiment, rather than by either the underfill material 400 alone (e.g., as in the first embodiment), or by the isolation material 170 alone (e.g., as in the second embodiment). Nevertheless, the third embodiment can still substantially achieve the same benefits discussed above with reference to the first embodiment or the second embodiment. For example, since the IC device 360 is located at least partially within the cavity 200, it can still achieve a closer distance to the IC device 110. This distance reduction can effectively reduce the parasitics, such as parasitic inductance and/or parasitic resistance, which in turn can improve device performance. In addition, since the underfill material 400 is covered up by the isolation material 170, the underfill material 400 is unlikely to spill out of the cavity 200 to encroach onto adjacent IC components such as the solder bump 350. The glue-like properties of the underfill material 400 allows it to maintain the attachment of the IC device 360 to the RDL1 layer. The combination of the underfill material 400 and the isolation material 170 can also effectively protect the components of the IC device 360 and/or the interconnection components 370 from contaminant particles or mechanical forces that could cause damage to the IC device 360.

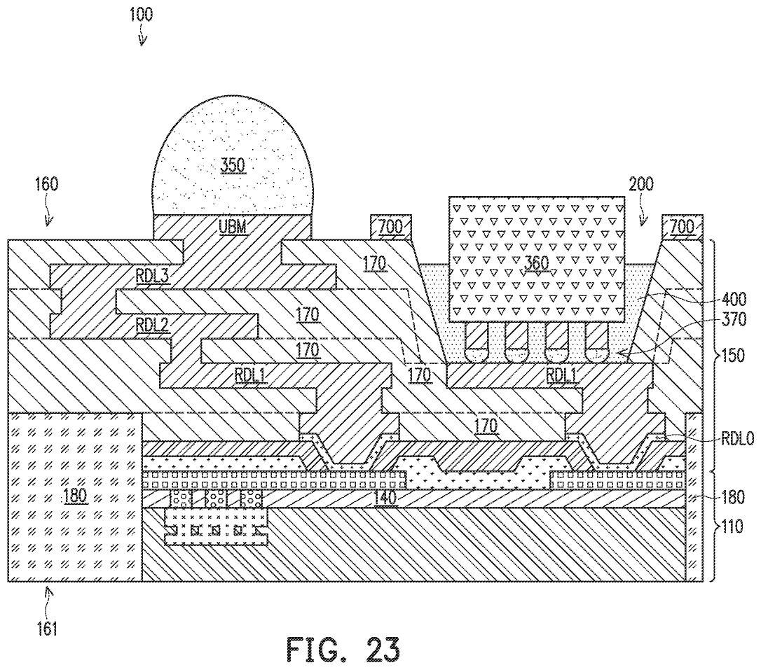

Based on the discussions above, it can be seen that each of the first, second, or third embodiment of the present disclosure can form an IC package 100 that embeds the IC device 360 at least partially within the cavity 200 formed on the side 160 of the interconnection structure 150. Such an implementation allows the underfill material 400 to be kept within the cavity 200 or even eliminated altogether. As a result, the likelihood of the underfill material 400 spilling out of the cavity and spreading onto nearby components (e.g., the solder bump 350) is substantially reduced. Nevertheless, the embodiments discussed above may be revised to include dam structures to further reduce the likelihood of the overspreading of the underfill material 400. These revisions of the first, second, and third embodiments above are illustrated in FIGS. 23-25, respectively.

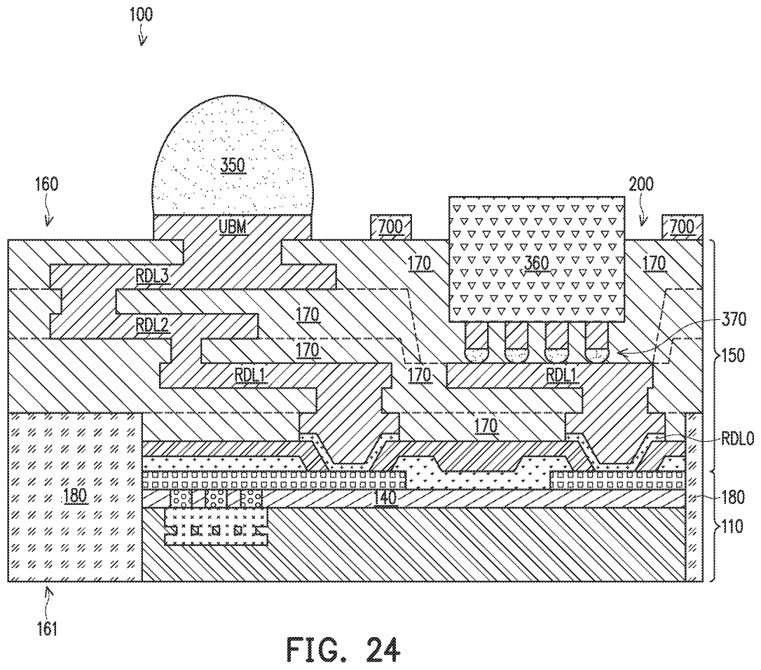

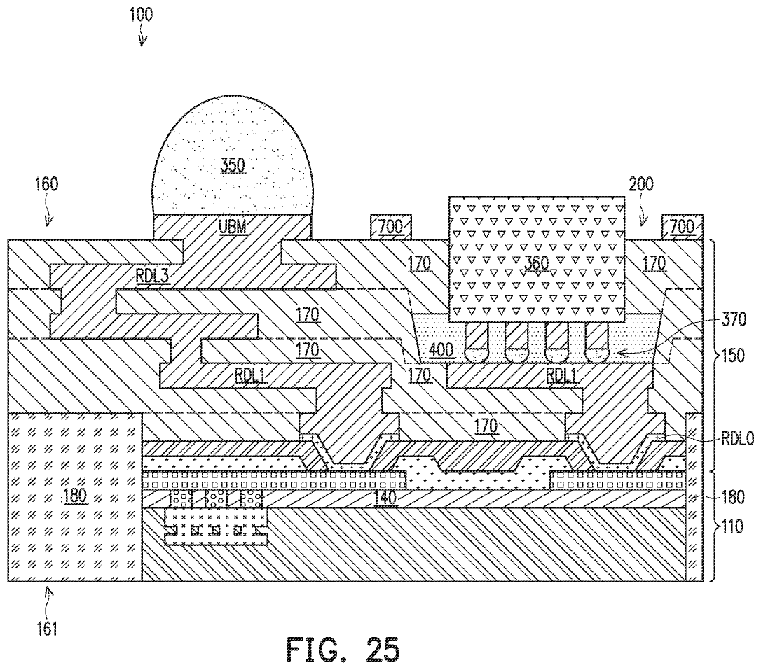

For example, the IC package 100 fabricated according to a variation of the first embodiment, the second embodiment, and the third embodiment of the present disclosure is illustrated in the cross-sectional side views of FIG. 23, FIG. 24, and FIG. 25, respectively. Specifically, a dam structure 700 is implemented over the side 160 of the interconnection structure 150, for example, on the upper surface of the uppermost isolation material 170. The dam structure 700 may circumferentially surround the IC device 360 in 360 degrees in a top view. In the cross-sectional side views of FIGS. 23-25, however, the dam structure 700 may appear as two vertically protruding pillars located on opposite sides of the IC device 360. The material composition of the dam structure 700 is flexibly configured. In the embodiments of FIGS. 23-25, the dam structure 700 has a same material composition as the UBM structure. For example, the dam structure 700 may be formed along with the UBM structure through the same fabrication processes used to form the UBM structure. The presence of the dam structure 700 can further impede the potential overspreading of the underfill material 400 (or the overspreading of the isolation material 170, if that would ever occur). As such, the components near to IC device 360 are even less likely to come into contact with the underfill material 400. Consequently, the implementation of the dam structure 700 can further reduce potential defects and further improve device performance.

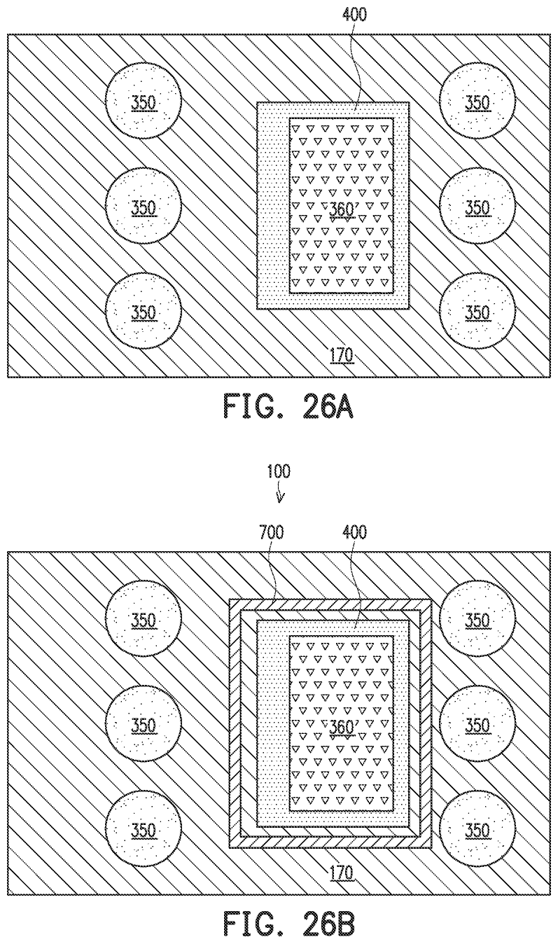

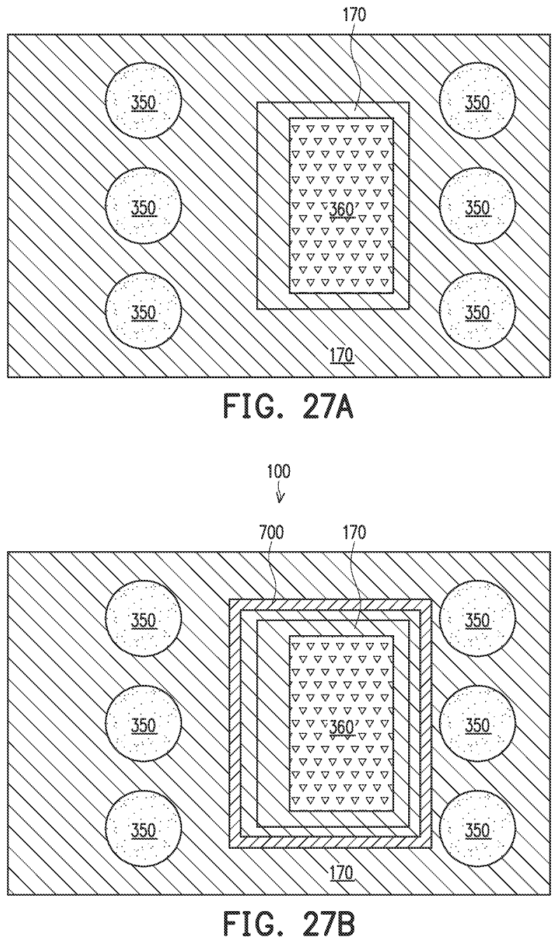

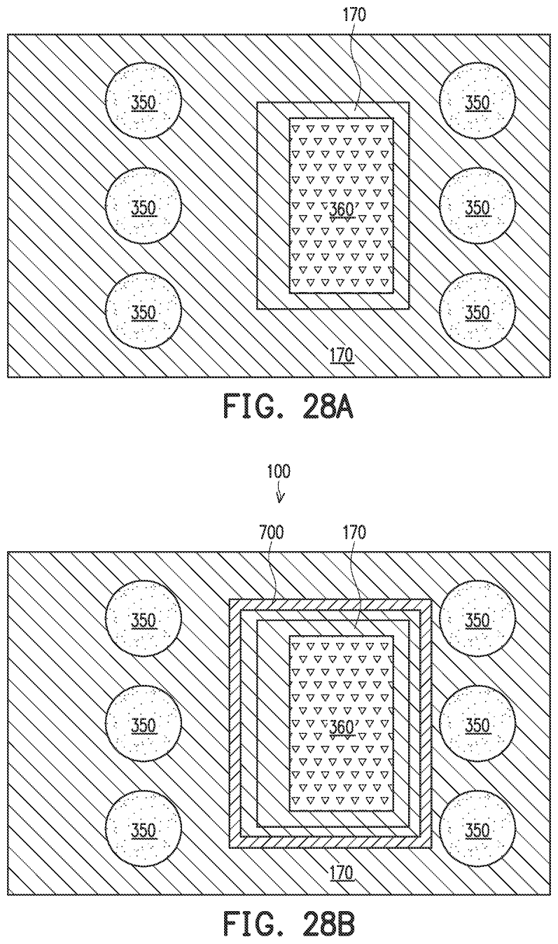

To further illustrate the various aspects of the present disclosure, the top views of the embodiments of the present disclosure are illustrated in FIGS. 26A-26B, 27A-28B, and 28A-28B. Specifically, FIG. 26A illustrates the top view of the IC package 100 fabricated according to the first embodiment of the present disclosure where the dam structure 700 is not implemented, and FIG. 26B illustrates the top view of the IC package 100 fabricated according to the variation of the first embodiment of the present disclosure where the dam structure 700 is implemented. FIG. 27A illustrates the top view of the IC package 100 fabricated according to the second embodiment of the present disclosure where the dam structure 700 is not implemented, and FIG. 27B illustrates the top view of the IC package 100 fabricated according to the variation of the second embodiment of the present disclosure where the dam structure 700 is implemented. FIG. 28A illustrates the top view of the IC package 100 fabricated according to the third embodiment of the present disclosure where the dam structure 700 is not implemented, and FIG. 28B illustrates the top view of the IC package 100 fabricated according to the variation of the third embodiment of the present disclosure where the dam structure 700 is implemented.

Referring now to FIGS. 26A and 26B, the underfill material 400 circumferentially surrounds the IC device 360 in 360 degrees. The outline of the underfill material 400 may be configured as a rectangle in the embodiments of FIGS. 26A-26B, though other geometric shapes may be configured in different embodiments. A plurality of solder bumps 350 are implemented nearby the IC device 360, for example, with a respective row on each side of the IC device 360. In the variation of the first embodiment shown in FIG. 26B, the dam structure 700 circumferentially surrounds the IC device 360 and the underfill material 400 in 360 degrees. The outline of the dam structure 700 may also be configured as a rectangle in the embodiment of FIG. 26B, though other geometric shapes may be configured in different embodiments.

Referring now to FIGS. 27A and 27B, the underfill material 400 is not implemented, but the portion of the isolation material 170 filling the cavity 200 circumferentially surrounds the IC device 360 in 360 degrees. The outline of the isolation material 170 may be configured as a rectangle in the embodiments of FIGS. 27A-27B, though other geometric shapes may be configured in different embodiments. A plurality of solder bumps 350 are implemented nearby the IC device 360, for example, with a respective row on each side of the IC device 360. In the variation of the second embodiment shown in FIG. 27B, the dam structure 700 circumferentially surrounds the IC device 360 and the isolation material 170 in 360 degrees. The outline of the dam structure 700 may also be configured as a rectangle in the embodiment of FIG. 27B, though other geometric shapes may be configured in different embodiments.

Referring now to FIGS. 28A and 28B, the top views in the third embodiment (and the variation thereof) appear substantially identical to the top views of the second embodiment (and the variation thereof) shown in FIGS. 27A and 27B, respectively. This is due to the fact that although the third embodiment implements the underfill material 400, the underfill material 400 is implemented below the isolation material 170 in the cross-sectional side view (see FIG. 25). As such, the isolation material 170, but not the underfill material 400, is visible in the top view.

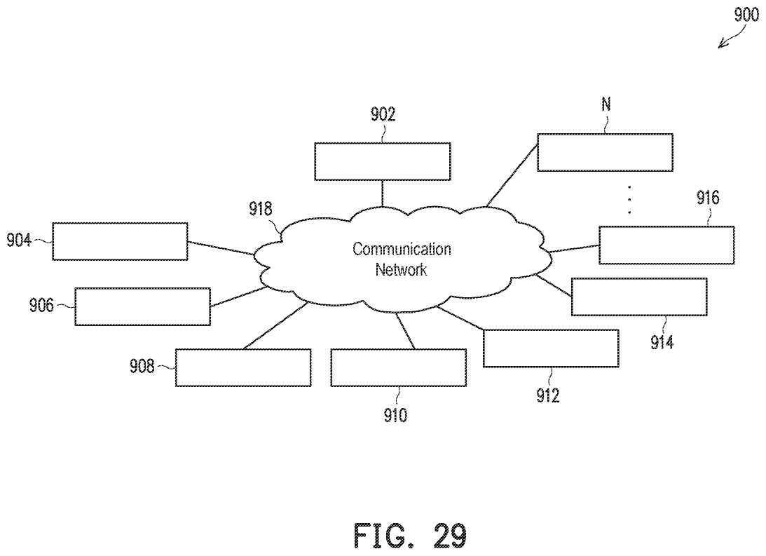

FIG. 29 illustrates an integrated circuit fabrication system 900 that may be used to fabricate the IC package 100 (or the components thereof, such as the IC device 110 or the IC device 360) according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the gate spacers of an SRAM device; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

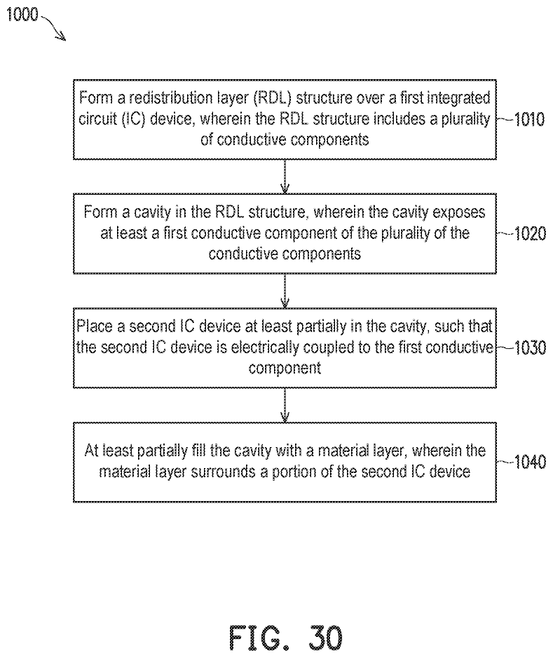

FIG. 30 is a flowchart illustrating a method 1000 according to an embodiment of the present disclosure. The method 1000 includes a step 1010 to form a redistribution layer (RDL) structure over a first integrated circuit (IC) device. The RDL structure includes a plurality of conductive components.

The method 1000 includes a step 1020 to form a cavity in the RDL structure. The cavity exposes at least a first conductive component of the plurality of the conductive components.

The method 1000 includes a step 1030 to place a second IC device at least partially in the cavity, such that the second IC device is electrically coupled to the first conductive component.

The method 1000 includes a step 1040 to at least partially fill the cavity with a material layer, wherein the material layer surrounds a portion of the second IC device.

In some embodiments, the step 1020 of forming the cavity comprises forming the cavity in a first layer of the RDL structure, forming a patterned photoresist layer over the RDL structure, wherein the patterned photoresist layer fills the cavity but exposes a second conductive component of the plurality of conductive components, forming an additional layer of the RDL structure over the second conductive component, and removing the patterned photoresist layer, thereby exposing the first conductive component to the cavity.

In some embodiments, the first IC device and the second IC device are different types of IC devices.

In some embodiments, the RDL structure is formed to include an isolation material that separates the plurality of conductive components from one another. In some embodiments, the at least partially filling the cavity comprises dispensing, through a nozzle, an underfill material into the cavity, wherein the underfill has a different material composition than the isolation material.

In some embodiments, the RDL structure is formed to include an isolation material that separates the plurality of conductive components from one another. In some embodiments, the at least partially filling the cavity comprises depositing an additional portion of the isolation material into the cavity such that the cavity is completely filled by the isolation material.

In some embodiments, the RDL structure is formed to include an isolation material that separates the plurality of conductive components from one another. In some embodiments, the at least partially filling the cavity comprises: dispensing, through a nozzle, an underfill material into the cavity. The underfill material has a different material composition than the isolation material. The at least partially filling the cavity also comprises coating an additional portion of the isolation material on the underfill material. The additional portion of the isolation material completely fills the cavity.

It is understood that additional processes may be performed before, during, or after the steps 1010-1040 of the method 1000. For example, the method 1000 may include a step of forming an under bump metallization (UBM) structure over the RDL structure, where the UBM structure is electrically coupled to a second conductive component of the plurality of conductive components. A solder bump is formed over the UBM structure. As another example, the method 1000 may include a step of forming a dam structure over the RDL structure, where the dam structure circumferentially surrounds the second IC device in a top view. For reasons of simplicity, other additional steps are not discussed herein in detail.

In summary, the present disclosure involves forming a cavity in an interconnection structure (e.g., an RDL structure) of an IC package, and implementing an IC device at least partially inside the cavity. The cavity is then filled with an underfill material, or with an isolation material, or by a combination of both. By doing so, the present disclosure offers advantages over conventional IC packages. It is understood, however, that other embodiments may offer additional advantages, and not all advantages are necessarily disclosed herein, and that no particular advantage is required for all embodiments. One advantage is reduction in overspreading of the underfill material. In that regard, conventional IC packages may lead to the formation of the underfill material on an upper surface of the RDL structure, which could potentially overspread to other nearby components such as a solder bump. A capillary effect may exacerbate this overspreading problem. If the underfill material comes into direct contact with the nearby components, it could adversely interfere with the intended operation of the IC package. Another advantage is the reduction is parasitics. As discussed above, since the IC device is implemented at least partially inside the cavity, it translates into a closer distance between the IC device and the SoIC device of the IC package. Had the cavity not been implemented, the IC device would have to be located on the upper surface of the RDL structure, which would then be farther from the SoIC device. The reduced distance between the IC device and the SoIC device may result in a lower parasitic inductance and/or a lower parasitic resistance, which would improve the overall performance of the IC package. Other advantages include compatibility with existing fabrication and/or packaging processes, so the present disclosure does not require additional processing and is therefore easy and cheap to implement.

One aspect of the present disclosure provides an IC package. The IC package includes a first integrated circuit (IC) device. An interconnection structure is disposed over the first IC device in a cross-sectional side view. The interconnection structure includes a plurality of interconnection components. A cavity is disposed in the interconnection structure in the cross-sectional side view. A second IC device is disposed at least partially within the cavity in the cross-sectional side view. The second IC device is electrically coupled to the first IC device through at least a subset of the interconnection components of the interconnection structure. A non-metallic material partially fills the cavity. The second IC device is at least partially surrounded by the non-metallic material in the cross-sectional side view and in a top view.

Another aspect of the present disclosure provides an IC package. The IC package includes a System on Integrated Chip (SoIC) device. A redistribution layer (RDL) structure is disposed over the SoIC device. The RDL structure includes an isolation material and a plurality of conductive components embedded in the isolation material. An Integrated Circuit (IC) device is embedded at least partially within the RDL structure. The IC device is electrically coupled to a first one of the conductive components of the RDL structure. An under bump metallization (UBM) structure is disposed over the RDL structure. The UBM structure is electrically coupled to a second one of the conductive components of the RDL structure.

Yet another aspect of the present disclosure provides a method. A redistribution layer (RDL) structure is formed over a first integrated circuit (IC) device. The RDL structure includes a plurality of conductive components. A cavity is formed in the RDL structure. The cavity exposes at least a first conductive component of the plurality of the conductive components. A second IC device is placed at least partially in the cavity, such that the second IC device is electrically coupled to the first conductive component. The cavity is at least partially filled with a material layer. The material layer surrounds a portion of the second IC device.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An integrated circuit (IC) package, comprising:
a first integrated circuit (IC) device;
an interconnection structure disposed over the first IC device in a cross-sectional side view, wherein the interconnection structure includes a plurality of interconnection components;
a cavity disposed in the interconnection structure in the cross-sectional side view;
a second IC device disposed at least partially within the cavity in the cross-sectional side view, wherein the second IC device is electrically coupled to the first IC device through at least a subset of the interconnection components of the interconnection structure; and
a non-metallic material partially filling the cavity, wherein the second IC device is at least partially surrounded by the non-metallic material in the cross-sectional side view and in a top view.

2. The IC package of claim 1, wherein:
the interconnection structure includes a plurality of redistribution layers disposed over one another in the cross-sectional side view;
each of the redistribution layers includes a different subset of the interconnection components; and
the cavity extends through multiple ones of the redistribution layers in the cross-sectional side view.

3. The IC package of claim 1, wherein:
the first IC device includes a System on Integrated Chip (SoIC) device; and
the second IC device includes a chip that includes a plurality of passive components but no transistors.

4. The IC package of claim 1, wherein:
the first IC device includes a System on Integrated Chip (SoIC) device; and
the second IC device includes a chip that includes transistors.

5. The IC package of claim 1, wherein an uppermost surface of the interconnection structure is more elevated vertically than an uppermost surface of the non-metallic material in the cross-sectional side view.

6. The IC package of claim 1, further comprising:
an under bump metallization (UBM) structure disposed over the interconnection structure in the cross-sectional side view, wherein no dam structure is disposed between the UBM structure and the second IC device in the top view; and
a solder bump disposed over the UBM structure in the cross-sectional side view.

7. The IC package of claim 1, wherein:
the interconnection structure includes an isolation material in which the interconnection components are embedded; and
the non-metallic material partially filling the cavity includes an underfill material having a different material composition than the isolation material.

8. The IC package of claim 1, wherein:
the interconnection structure includes an isolation material in which the interconnection components are embedded; and
the non-metallic material partially filling the cavity has a same material composition as the isolation material.

9. The IC package of claim 1, wherein:
the interconnection structure includes an isolation material in which the interconnection components are embedded; and
the non-metallic material partially filling the cavity includes both the isolation material and an underfill material having a different material composition than the isolation material.

10. An integrated circuit (IC) package, comprising:
a System on Integrated Chip (SoIC) device;
a redistribution layer (RDL) structure disposed over the SoIC device, wherein the RDL structure includes an isolation material and a plurality of conductive components embedded in the isolation material;
an Integrated Circuit (IC) device embedded at least partially within the RDL structure, wherein the IC device is electrically coupled to a first one of the conductive components of the RDL structure; and
an under bump metallization (UBM) structure disposed over the RDL structure, wherein the UBM structure is electrically coupled to a second one of the conductive components of the RDL structure.

11. The IC package of claim 10, wherein:
the RDL structure includes an isolation material and an underfill material having a different material composition than the isolation material; and
the IC device is embedded at least partially in the underfill material.

12. The IC package of claim 10, wherein the IC device includes an Integrated Passive Device (IPD).

13. A method, comprising:
forming a redistribution layer (RDL) structure over a first integrated circuit (IC) device, wherein the RDL structure includes a plurality of conductive components;
forming a cavity in the RDL structure, wherein the cavity exposes at least a first conductive component of the plurality of the conductive components;
placing a second IC device at least partially in the cavity, such that the second IC device is electrically coupled to the first conductive component; and
at least partially filling the cavity with a material layer, wherein the material layer surrounds a portion of the second IC device.

14. The method of claim 13, further comprising:
forming an under bump metallization (UBM) structure over the RDL structure, wherein the UBM structure is electrically coupled to a second conductive component of the plurality of conductive components; and
forming a solder bump over the UBM structure.

15. The method of claim 13, further comprising: forming a dam structure over the RDL structure, wherein the dam structure circumferentially surrounds the second IC device in a top view.

16. The method of claim 13, wherein the forming the cavity comprises:
forming the cavity in a first layer of the RDL structure;
forming a patterned photoresist layer over the RDL structure, wherein the patterned photoresist layer fills the cavity but exposes a second conductive component of the plurality of conductive components;
forming an additional layer of the RDL structure over the second conductive component; and
removing the patterned photoresist layer, thereby exposing the first conductive component to the cavity.

17. The method of claim 13, wherein the first IC device and the second IC device are different types of IC devices.

18. The method of claim 13, wherein:
the RDL structure is formed to include an isolation material that separates the plurality of conductive components from one another; and
the at least partially filling the cavity comprises dispensing, through a nozzle, an underfill material into the cavity, wherein the underfill material has a different material composition than the isolation material.

19. The method of claim 13, wherein:
the RDL structure is formed to include an isolation material that separates the plurality of conductive components from one another; and
the at least partially filling the cavity comprises depositing an additional portion of the isolation material into the cavity such that the cavity is completely filled by the isolation material.

20. The method of claim 13, wherein:
the RDL structure is formed to include an isolation material that separates the plurality of conductive components from one another; and
the at least partially filling the cavity comprises:
dispensing, through a nozzle, an underfill material into the cavity, wherein the underfill material has a different material composition than the isolation material; and
thereafter coating an additional portion of the isolation material on the underfill material, wherein the additional portion of the isolation material completely fills the cavity.
